(19) United States
(12) Patent Application Publication
(10) Pub. No.: US 2006/0285619 A1
(43) Pub. Date: Dec. 21, 2006

(54) Digital control oscillator

(75) Inventor: Masafumi Watanabe, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/451,406

(22) Filed: Jun. 13, 2006

(30) Foreign Application Priority Data
Jun. 20, 2005 (JP) 2005-179136

(51) Int. Cl. H03D 3/24

(52) U.S. Cl. 375/376

(57) ABSTRACT

A digital control oscillator includes a reference signal generation circuit for generating a first reference signal of a first signal level, and a second reference signal of a second signal level, a conversion circuit for referring to the first and the second reference signals, and converting a digital signal being inputted into an analog output control signal in a range from the first signal level to the second signal level, and an output oscillator for outputting clocks having a frequency corresponding to the output control signal.

### BACKGROUND OF THE INVENTION

1. Field of the Invention

The present invention relates to a digital control oscillator, and particularly to a digital control oscillator for converting a digital signal into an analog signal, and outputting a clock having a frequency that corresponds to the analog signal.

2. Description of the Related Art

A digital control oscillator is conventionally used for regenerating a clock from a digital signal (clock recovery) in record/playback device, communication device, and television signal processor and the like. The digital control oscillator is a circuit for outputting a clock having a frequency corresponding to a digital data.

For example a record/playback device such as a DVD (Digital Versatile Disc), a DVC (Digital Video Cassette), and a HDD (Hard Disk Drive) generates a synchronous clock necessary for recording/playing by a circuit called a digital read channel. Inside the digital read channel, a digital control oscillator is provided. A phase difference between a digital data read from DVD etc and a clock of the digital control oscillator is detected, and a feedback of the phase difference data is input to the digital control oscillator so as to regenerate a clock.

In recent years, with an advance in high density digital data to be recorded as represented by DVD and HDD, a clock recovery technique with higher accuracy is demanded for. Especially for DVD, a synchronous clock differs in inner periphery and outer periphery, and a DVD needs to support special playback including fast and slow motion play. Accordingly a wider range (frequency variable range) from a minimum frequency (lower limit frequency) to a maximum frequency (upper limit frequency) and a higher resolving power are required.

A conventional digital oscillator disclosed in Japanese Unexamined Patent Publication No. 2003-23354 is well known. FIG. 8 shows a configuration of a conventional digital control oscillator disclosed in Japanese Unexamined Patent Publication No. 2003-23354. As shown in FIG. 8, the conventional digital control oscillator includes a PLL (Phase Locked Loop) 900, a DAC (Digital Analog Converter) 910, CCO (Current Controlled Oscillator) 911. The PLL 900 includes a 1/M divider 901, a phase detector 902, a loop filter 903, a VIC (Voltage to Current Converter) 904, a current mirror circuit 905, a CCO 906, and a 1/N divider 907.

In a conventional digital control oscillator, the DAC 910 converts a digital control data DF that is supplied externally into an analog control current Idac, and the CCO 911 outputs a clock CKo to outside having an output frequency fo that corresponds to the control current Idac.

DAC 910 uses a control current Ics that is supplied by the PLL 900 as a reference current for D/A conversion. The-PLL 900 generates a dividing clock CKm, which is a reference clock supplied externally being divided by M in the 1/M divider 901, and at the same time, the CCO 906 generates an internal clock CKi having an oscillation frequency f1 that corresponds to the control current Ics, and the 1/N divider 907 generates a dividing clock CKn, which is the internal clock CKi being divided by N. Further, the phase detector 902 detects a phase difference between the dividing clock CKm and the dividing clock CKn, and generates a phase difference signal Sp having a pulse width corresponding to the phase difference. The loop filter 903 filters the phase difference signal Sp and generates a control voltage Vcs. Further, the VIC 904 converts the control voltage Vcs into the control current Ics, and the current mirror circuit 905 supplies the control current Ics to the DAC 910 and the CCO 906.

FIGS. 9A to 9C show each characteristic of a conventional digital control oscillator. FIG. 9A shows a characteristic of a control data DF—the control current Idac in the DAC 910, that is, a characteristic of the control current Idac to be supplied to the CCO 911 as against the control data DF being inputted. FIG. 9B shows a characteristic of the control current Idac—the output frequency fo in the CCO 911, that is, a characteristic of the output frequency fo for the clock CKo to be outputted as against the control current Idac being inputted. FIG. 9C shows a characteristic of the control data DF—the output frequency fo in a conventional digital control oscillator, that is, a characteristic of the output frequency fo for the clock CKo to be outputted as against the control data DF being input, that is obtained from FIGS. 9A and 9B.

As shown in FIG. 9A, when the control data DF in a range from a lower limit 0, to an upper limit DFmax is inputted to the DAC 910, the DAC 910 outputs a control current Idac that is in proportion to the control data DF. A center value of the control data DF is DFmax/2. The DAC 910 performs D/A conversion with the control current Ics as a reference current, which is a center current of the output in this example. Accordingly when the control data DF is the center value DFmax/2, the control current Idac will be the control current Ics. When the control data DF is a lower limit value “0”, the control current Idac will be the control current Ics×(1−α). When the control data DF is an upper limit value DFmax, the control current Idac will be the control current Ics×(1+α).

Further, as shown in FIG. 9B, the CCO 911 outputs a clock CKo having an output frequency fo that is in proportion to the control current Idac being inputted. In this example, a control current Ics is the center value of the control current Idac, and when the control current Ics is inputted, the output frequency fo will be a center frequency fc.

By combining the characteristic of the DAC 910 shown in FIG. 9A and that of the CCO 911 shown in FIG. 9B, with a characteristic of the conventional digital control oscillator as shown in FIG. 9C, a clock CKo is outputted having an output frequency fo that is in proportion to the control data DF in a range from the lower limit value 0 to the upper limit DFmax. When the control data DF is the center value DFmax/2, the control current Ics is inputted to the CCO 911, and the output frequency fo will be the center frequency fc. When the control DF is the lower limit 0, the control current Ics×(1−α) is inputted to the CCO 911, and the output frequency fo will be a lower limit frequency fcs×(1−α).

In a conventional digital control oscillator, the PLL 900 is constituted of the CCO 906 having an identical configuration with the CCO 911, and the PLL 900 is locked to a center frequency c of the CCO 911 so as to be a center of the control current Idac, that is supplied from the DAC 910 to the CCO 911. In other words, the center frequency of the output from the digital control oscillator is fixed by the oscillation frequency of the PLL 900.

This prevents from an input current—output frequency characteristic of the CCO from changing as well as the center frequency from fluctuating, which is caused by variations in production tolerance and a difference in surrounding environment such as a temperature difference and power supply voltage etc.

However it has been discovered that with a conventional digital control oscillator, even in a case in which a center frequency of an output is fixed, an frequency could fluctuate in a range outlying the center frequency, thereby deteriorating a performance of the digital control oscillator.

FIGS. 10A to 10C show an example of a fluctuation of frequency generated in a conventional digital control oscillator. In the similar manner as FIGS. 9A to 9C, FIG. 10A shows a characteristic of the input control data DF—the output current Idac in the DAC 910. FIG. 10B shows a characteristic of the input current Idac—the output frequency fo in the CCO 911. FIG. 10C shows a characteristic of the input control dada—the output frequency fo in a conventional digital control oscillator.

As shown in FIG. 10A, as an environment such as temperature changes, a characteristic of the control current Idac against the control data DF also changes to y101, y102, and y103. This is because that a characteristic of the CCO 906 in the PLL 900 fluctuates due to a change in an environment, thereby changing the control current Ics In FIG. 10A, as the control data DF becomes larger, the fluctuation of the control current Idac becomes larger as well.

Further, as shown in FIG. 10B, as an environment such as temperature changes, a characteristic of the control current Idac against the control current Idac also changes to y111, y112, and y113. In FIG. 10B, as the control current Idac becomes larger, fluctuation of the output frequency fo becomes larger as well. For example, y111 and y101 are characteristics under the same condition, y112 and y102 are characteristics under the same condition, and y113 and y103 are characteristics under the same condition.

By combining the characteristic of the DAC 910 shown in FIG. 10A and the characteristic of the CCO 911 shown in FIG. 10B, a characteristic of the output frequency fo against the control data DF changes to y121, y122, and y123 as environment such as temperature changes. That is, a slope of the characteristic for the digital control oscillator changes in response to a change in environment.

As described in the foregoing, with the center value Dfmax/2 of the control data DF, the output frequency fo does not fluctuate even if an environment changes. However in a range outlying the center value DFmax/2, the output frequency fo fluctuates as an environment changes. For example the output frequency fo fluctuates the most at a lower limit value “0” or an upper limit value DFmax of the control data DF. Because the slope of the characteristic fluctuates, the upper and lower limit value of the output frequency fo changes, thereby causing the output frequency fo range to deviate from a desired range.

FIGS. 10A to 10C show an example in which a characteristic of the CCO changes due to a change in environment etc. However the characteristic of the CCO may not be as desired depending on a circuit configuration of the CCO and the like. FIGS. 11A and 11B show another example of a fluctuation of a frequency generated in a conventional digital control oscillator. FIG. 11A shows a characteristic of the input current Idac—the output frequency fo in the CCO 911. FIG. 11B shows a characteristic of the input control data DF—the output frequency fo in the conventional digital control oscillator.

As shown in FIG. 11A, the characteristic of the output frequency fo against the control current Idac may be formed to be a curved line as with y201, not an ideal straight line as with y202, depending on a circuit configuration of the CCO. In this example, the characteristic y201 is a concave upward.

As shown in FIG. 11B, the characteristic of the output frequency fo against the control data DF is a curved line. The characteristic y211 is almost the same as the ideal characteristic y212, from a center to the upper limit value DFmax of the control data DF. However as the control data DF becomes smaller than a center value, the line of the characteristic y211 moves away from the ideal characteristic y212. When the control data DF is around the lower limit value “0”, the output frequency fo largely moves downward from an ideal lower limit frequency. Accordingly a range of the output frequency fo extends more than the desired range.

In a reverse way as the FIGS. 11A and 11B, the characteristic of the CCO may be formed to be a concave upward. In this case, the characteristic is shaped almost as ideal from a center to the lower limit value “0” of the control data DF. However as the control data DF becomes larger than the center value, the characteristic moves away from the ideal characteristic, and the output frequency fo largely moves upward when the control data DF is around the upper limit value DFmax. Thus also in this case, the range of the output frequency fo extends more than the desired range.

As described in the foregoing, with a conventional digital control oscillator, a center frequency of an output can be maintained to be constant, however in a range outlying a center, an output frequency fluctuates, eventually fluctuating an upper and a lower limit value of the output frequency. It is therefore difficult to keep the frequency variable range constant. If the frequency variable range extends, an output frequency that varies per bit of the control data DF being input becomes larger, thereby lowering a resolving power of the output frequency and a performance of the digital control oscillator.

Furthermore, even when leaving an extra in a desired frequency variable range, assuming a case that the frequency variable range becomes smaller, the resolving power of the output frequency declines, causing to deteriorate the performance.

### SUMMARY OF THE INVENTION

According to an aspect of the present invention, there is provided a digital control oscillator that includes a reference signal generation circuit for generating a first reference signal of a first signal level and a second reference signal of a second signal level, a conversion circuit for converting a digital signal being input into an analog output control signal having a range from the first signal level to the second signal level, and an output oscillator for outputting a clock having a frequency corresponding to the output control signal.

With this digital control oscillator, an upper and a lower limit of the output clock frequency can be fixed by inputting control signals from the first signal level to the second signal level to the output oscillator. This helps keep the frequency variable range to be constant even when a characteristic of the oscillator fluctuates, and prevents the resolving power from declining, thereby restraining the performance of the digital control oscillator from deteriorating.

According to another aspect of the present invention, there is provided a digital control oscillator that includes a conversion circuit for converting a digital signal being inputted into an analog output control signal, an output oscillator for outputting a clock having a frequency corresponding to the output control signal, and a control circuit for controlling an upper and a lower limit value of the output control signal to be a specified value.

With the digital control oscillator, by controlling an upper and a lower limit value of a control signal inputted to an output oscillator to a specified value, a frequency variable range can be kept constant and the resolving power can be prevented from declining, thereby reducing a performance deterioration of the digital control oscillator.

The present invention provides a digital control oscillator that reduces a fluctuation of a variable range of an output frequency and suppresses performance deterioration.

### BRIEF DESCRIPTION OF THE DRAWINGS

The above and other objects, advantages and features of the present invention will be more apparent from the following description taken in conjunction with the accompanying drawings, in which:

FIG. 1 is a block diagram showing a configuration of a digital control oscillator according to the present invention;

FIG. 2 is a circuit diagram showing a configuration of a conversion circuit that constitutes the digital control oscillator according to the present invention;

FIG. 3 is a circuit diagram showing a configuration of a CCO that constitutes the digital control oscillator according to the present invention;

FIGS. 4A to 4C are views showing characteristics of the digital control oscillator according to the present invention;

FIG. 5 is a view showing a characteristic of the digital control oscillator according to the present invention;

FIG. 6 is a block diagram showing a configuration of the digital control oscillator according to the present invention;

FIGS. 7A and 7B are views showing characteristics of the digital control oscillator according to the present invention;

FIG. 8 is a block diagram showing a configuration of the digital control oscillator according to a conventional technique;

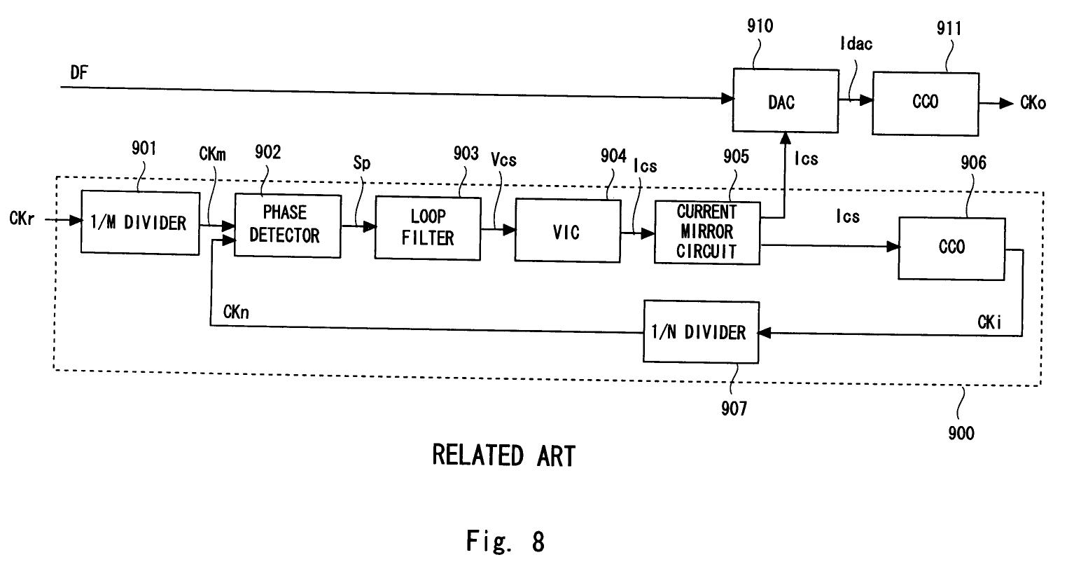

FIGS. 9A to 9C are views showing characteristics of the digital control oscillator according to a conventional technique;

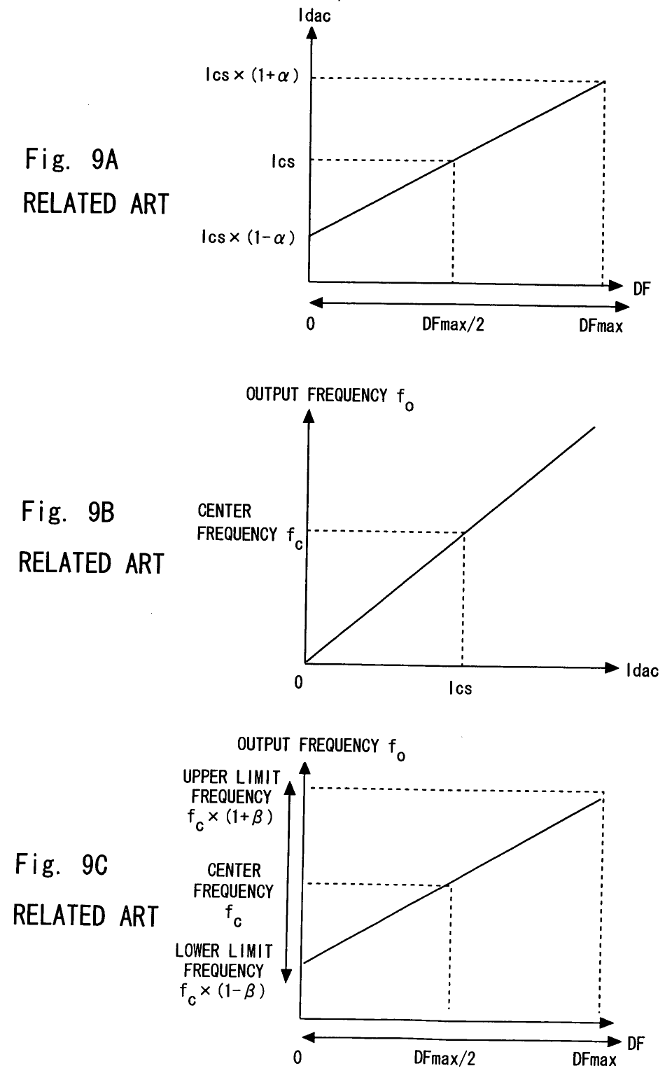

FIGS. 10A to 10C are views showing characteristics of the digital control oscillator according to a conventional technique; and

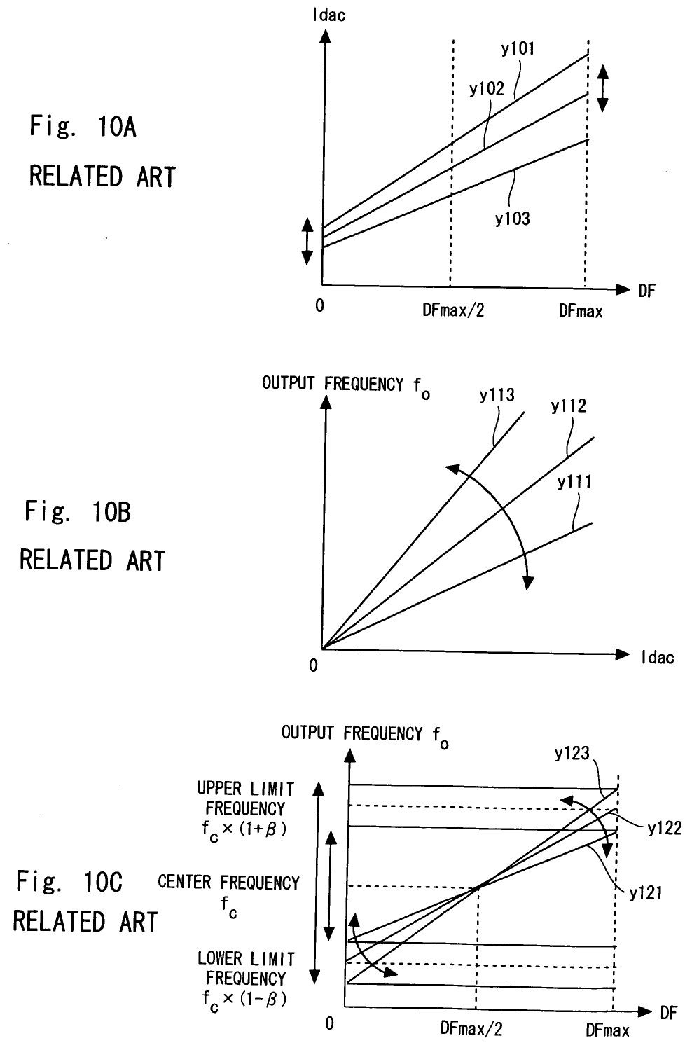

FIGS. 11A and 11B are views showing characteristics of the digital control oscillator according to a conventional technique.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Embodiment

A digital control oscillator according to a first embodiment of the present invention is described hereinafter in detail. The digital control oscillator of this embodiment is characterized by controlling an upper and lower limit of an output frequency to be fixed using two PLLs.

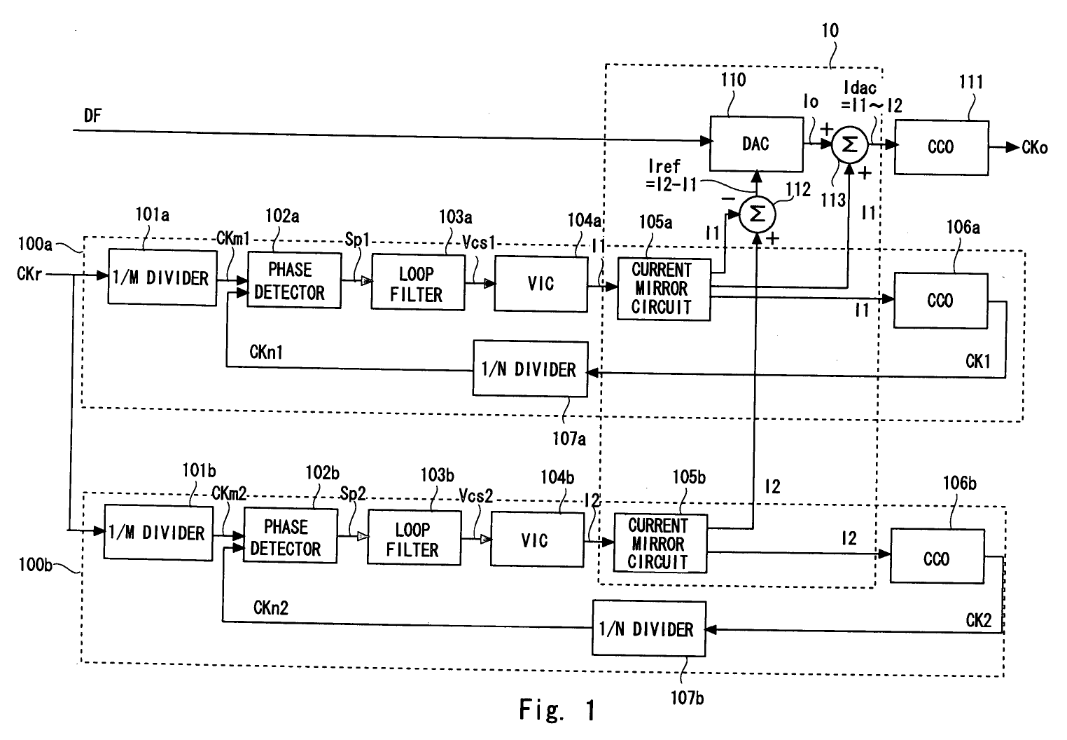

A configuration of the digital control oscillator of this embodiment is described hereinafter in detail with reference to FIG. 1. The digital control oscillator outputs a clock CKo having an output frequency fo that corresponds to a digital control data DF being inputted. As shown in FIG. 1, the digital control oscillator includes PLLs 100a and 100b, a DAC 110, a CCO 111, and current addition/subtraction circuits 112 and 113.

For example the PLL 100a and the PLL 100b are reference signal generation circuits for generating a control current I1 (a first reference signal) and a control current I2 (a second reference signal). The PLL 100a and the PLL 100b are also control circuits for controlling an upper and lower limit of a control current Idac, that is inputted to the CCO 111. The PLL 100a (a first PLL circuit) generates the control current I1 based on a reference clock CKr, and also locks an oscillation frequency to a frequency f1 (a first frequency) by the control current I1. The PLL 100b (a second PLL circuit) generates a control current I2, and also locks an oscillation frequency to a frequency f2 (a second frequency) by the control current I2. In this example, the frequency f1 is a lower limit frequency of the output frequency fo, while the frequency f2 is an upper limit frequency of the output frequency fo.

For example the current addition/subtraction circuits 112 and 113, and the DAC 110 form a conversion circuit 10 that refers to the control currents I1 and I2, and converts the control data DF into a control signal with a range from the control current I1 to the control current I2. The control current I1 is a signal corresponding to a lower limit value of the control signal Idac, and the control current I2 is a signal corresponding to an upper limit value of the control signal Idac.

The current addition/subtraction circuit 112 adds/subtracts the control current I1, supplied from the PLL 100a, and the control current I2, supplied from the PLL 100b, to generate a reference current Iref. In this example, the current addition/subtraction circuit 112 subtracts the control current I1 from the control current I2, and supplies a differential signal to the DAC 110 as the reference current Iref.

The DAC 110 is a current output type, in which the DAC 110 converts a control data DF, supplied externally, into an analog current Io. In this embodiment, the DAC 110 takes the reference current Iref, supplied from the current addition/subtraction circuit 112, as a maximum reference current, and generates the analog current Io, with the reference current Iref (i.e. control current I2−I1) as an upper limit.

The current addition/subtraction circuit 113 adds/subtracts the analog current Io and the control current I1, supplied from the PLL 100a, and generates the control current Idac. In this example, the current addition/subtraction circuit 112 adds the control current I1 to the analog current Io, and supplies the added signal to the CCO 111 as the control current Idac. Specifically, the current addition/subtraction circuit 113 converts the analog current Io, with an upper limit of the control current I2−I1, into the control current Idac, having a range from the current control I1 to the control current I2.

The CCO 111 is an output oscillator for outputting a clock CKo having an output frequency fo that corresponds to the control current Idac, supplied from the current addition/subtraction circuit 113. The CCO 111 generates the clock CKo having the output frequency fo from the lower limit frequency f1 to the upper limit frequency f2, corresponding to the control current Idac from the control current I1 to the control current I2.

Configurations of the PLL 100a and the PLL 100b are described hereinafter in detail. The configurations of the PLL 100a and the PLL 100b are the same. The PLL 100a includes a 1/M divider 101a, a phase detector 102a, a loop filter 103a, a VIC 104a, a current mirror circuit 105a, a CCO 106a, and a 1/N divider 107a. The PLL 100b includes a 1/M divider 101b, a phase detector 102b, a loop filter 103b, a VIC 104b, a current mirror circuit 105b, a CCO 106b, and a 1/N divider 107b.

In the PLL 100a, the 1/M divider 101a (a second divider) divides a reference clock CKr having a frequency fr, inputted externally, by M. Then the PLL 100a supplies the divided clock Ckm1 having a frequency fm1 (i.e. fr/M) to the phase detector 102a.

The CCO 106a (a first PLL oscillator) generates an internal clock CK1 having a frequency f1 corresponding to the control current I1 and supplies the internal clock to the 1/N divider 107a. The 1/N divider 107a (a first divider) divides the internal clock having the frequency f1, that is supplied from the CCO 106a, by N1. Then the 1/N divider 107a supplies the divided clock having a frequency fn1 (i.e. f1/N) to the phase detector 102a as a divided clock CKn1.

The phase detector 102a (a first phase detector) detects a phase difference between the divided clock CKm1, supplied from the 1/M divider 101a, and the divided clock CKn1, supplied from the 1/N divider 107a. The phase detector 102a then supplies a phase difference signal Sp1 having a pulse width corresponding the phase difference to the loop filter 103a.

The loop filter 103a smoothes and filters the phase difference by charging/discharging to an internal condenser based on the phase difference signal Sp1, which is supplied from the phase detector 102a, and generates a control voltage Vcs1 to be supplied to the VIC 104a.

The VIC 104a (a first reference signal conversion circuit) converts a control voltage Vcs1, supplied from the loop filter 103a, into the control current I1. The VIC 104a then supplies the control current I1 to the current mirror circuit 105a. The current mirror circuit 105a (a first current mirror circuit) generates the same current as the control current I1, supplied from the VIC 104a. The current mirror circuit 105a then supplies the generated control current I1 to the current addition/subtraction circuits 112 and 113, and the CCO 106a. The current mirror circuit 105a outputs the control current I1 for controlling a lower limit value of the control signal Idac, and for controlling an oscillation of the frequency f1.

The PLL 100b and the PLL 100a have the same configuration, in which they define the oscillation frequencies f1 and f2 and the control current I1 and I2 according to dividing ratios of the 1/M divider 101a and the 1/N divider 101a. Accordingly by changing the dividing ratios of the dividers, a lower and an upper limit frequency of the digital control oscillator can be changed.

The 1/M divider 101b (a fourth divider) divides the reference clock CKr by M to generate a divided clock CKm2 having a frequency fm2 (i.e. fr/M2). The CCO 106b (a second PLL oscillator) generates an internal clock CK2 having a frequency f2 corresponding to the control current I2. The 1/N divider 107b (a third divider) divides the internal clock CK2 by N2, and generates a divided clock Ckn having a frequency fn2 (i.e. f2/N2).

The phase detector 102b (a second phase detector) detects a phase difference between the divided clock CKm2 and the divided clock CKn2, and generates a phase difference signal Sp2 corresponding to the phase difference. The loop filter 103b filters the phase difference signal Sp2, and generates a control voltage Vcs2. The VIC 104b (a second reference signal conversion circuit) converts the control voltage Vcs1 into the control current I2.

The current mirror circuit 105b (a second current mirror circuit) generates the same current as the control current I2, supplied from the VIC 104b. The current mirror circuit 105b then supplies the generated control current I2 to the current addition/subtraction circuit 112 and the CCO 106b. The current mirror circuit 105b outputs the control current I2 for controlling an upper limit value of the control signal Idac, and for controlling an oscillation of the frequency f2.

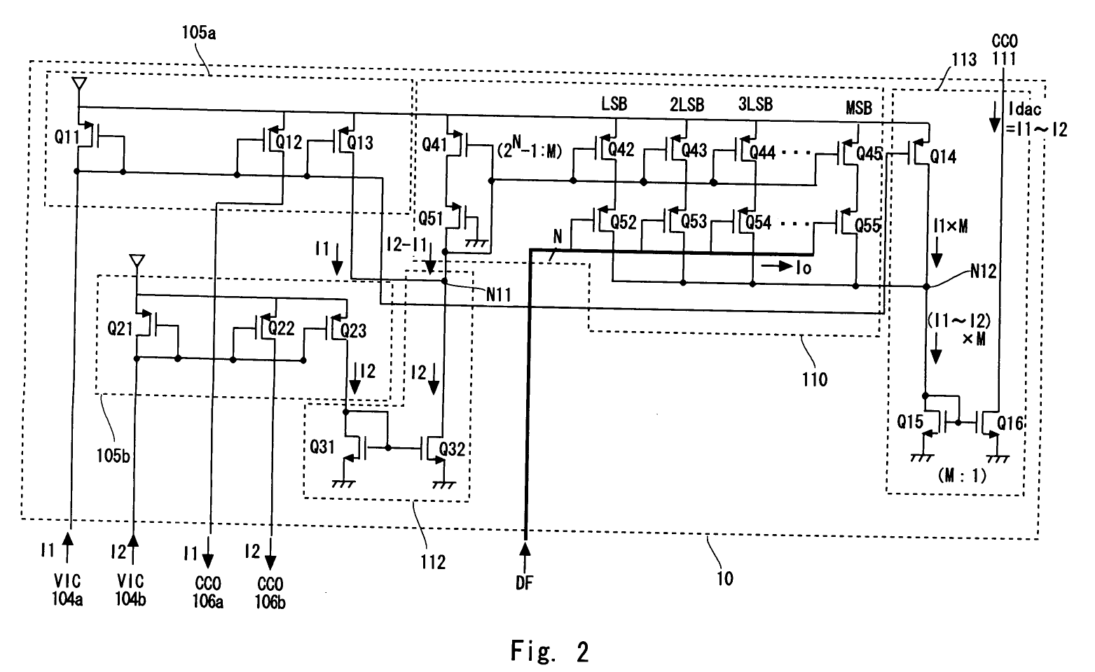

An example of configuration of the conversion circuit 10 comprising the DAC 110 is described hereinafter in detail with reference to FIG. 2. FIG. 2 shows a circuit configuration of the DAC 110, the current mirror 105a and 105b, the current addition/subtraction circuits 112 and 113.

As shown in FIG. 2, the conversion circuit 10 comprises P-channel MOS transistors Q11 to Q14, Q21 to Q23, Q41 to Q45, Q51 to Q55, and N-channel MOS transistors Q15, Q16, Q31, and Q32.

The current mirror circuit 105a comprises the MOS transistors Q11, Q12, and Q13, that are connected to form current mirrors. To be specific, sources of the MOS transistors Q11 to Q13 are connected to a power supply potential, gates of the MOS transistors Q11 to Q13 are connected to each other, and the gates are commonly connected to a drain of the MOS transistor Q11.

Generally a current mirror circuit generates a current complying to a ratio of a size of each MOS transistor (gate width W/gate length L). In this example, the MOS transistors Q11 to Q13 are the same size. For example if the control current I1 is supplied from the VIC 104a to the drain of the MOS transistor Q11, the same control current I1 flows to the MOS transistors Q12 and Q13. The control current I1 is supplied from the MOS transistor Q12 to the CCO 106a, and the control current I1 is supplied from the MOS transistor Q13 to the current addition/subtraction circuits 112 and 113.

The current mirror circuit 105a comprises the MOS transistors Q21, Q22, and Q23, that are connected to form current mirrors. To be specific, sources of the MOS transistors Q21 to Q23 are connected to a power supply potential, gates of the MOS transistors Q21 to Q23 are connected to each other, and the gates are also commonly connected to a drain of the MOS transistor Q21. In this example, the MOS transistors Q21 to Q23 are the same size.

For example if the control current I2 is supplied from the VIC 104b to the drain of the MOS transistor Q21, the same control current I2 flows to the MOS transistors Q22 and Q23. The control current I1 is supplied from the MOS transistor Q12 to the CCO 106a, and the control current I1 is supplied from the MOS transistor Q13 to the current addition/subtraction circuits 112 and 113.

The current addition/subtraction circuit 112 comprises MOS transistors Q31 and Q32, that are connected to form current mirrors. To be specific, sources of the MOS transistors Q31 and Q32 are connected to a ground potential, gates are connected to each other, and the gates are also commonly connected to a drain of the MOS transistor Q31. Further, the drain of the MOS transistor Q31 is connected to the drain of the MOS transistor Q23. The drain of the MOS transistor Q32 is connected to the drain of the MOS transistor Q13 through a node N11. In this example, the MOS transistors Q31 and Q32 are the same size.

For example if the control current I2 is supplied from the VIC 105b to the drain of the MOS transistor Q31, the same control current I2 flows to the MOS transistors Q32 and Q23. Then the control current I1 flows from the MOS transistor Q13 to the node N11, and the control current I2 flows from the node N11 to the MOS transistor Q32. As a result, a current value of the node N11 becomes the reference current Iref=the control current I2−the control current I1. This current value of the node N11 is supplied to the DAC 110.

The DAC 110 comprises MOS transistors Q41 to Q45 and Q51 to Q55. The MOS transistors Q41 and Q51 are connected in series, the MOS transistors Q42 and Q52 are connected in series, the MOS transistors Q43 and Q53 are connected in series, the MOS transistors Q44 and Q54 are connected in series, and the MOS transistors Q45 and Q55 are connected in series.

As the DAC 110 is regarded to convert N bit control data DF from digital to analog, the MOS transistors Q42 to Q45, and Q52 to Q66 are provided to support 1 bit to N−1 bit. For example the MOS transistors Q42 and Q52 convert LSB (least Significant Bit), the MOS transistors Q43 and Q53 convert 2LSB (second bit from the LSB), the MOS transistors Q44 and Q54 convert 3LSB (third bit from the LSB), and the MOS transistors Q45 and Q55 convert MSB (Most Significant Bit).

A gate of the MOS transistor Q51 is connected to a ground potential, and is provided between the MOS transistor Q41 and the node N11. The MOS transistors Q41 and the MOS transistors Q42 to Q45 are connected to form current mirrors. Sources of the MOS transistors Q41 to Q45 are connected to a power supply potential, gates of the MOS transistors Q41 to Q45 are connected to each other, and the gates are also commonly connected to a drain of the MOS transistor Q51. Gates of the MOS transistors Q52 to Q55 are supplied with bits corresponding to the control data DF, drains are connected to each other, and the drains are also commonly connected to the node N12. The MOS transistor Q51 includes a function to generate a bias condition in the MOS transistor Q41, which is similar to a bias condition generated in the MOS transistors Q42 to Q45 when the MOS transistors Q52 to Q55 are turned on. However, DAC 110 is able to function as a D/A converter even without the MOS transistor Q51.

Size ratio of the MOS transistors Q41 to Q45 are weighted to a specified amount. For example suppose that a size ratio (gate width W/gate length L) of the MOS transistor Q42 to be M, and a size ratio of the MOS transistor Q41 to be 2ⁿ⁻¹. If M=1, a current that flows the MOS transistor Q42 is 1/(2ⁿ⁻¹) of a current that flows the MOS transistor Q41, which is extremely small and may be susceptible to an influence of noise. It is therefore preferable that M is to be a value to make the current of the MOS transistor Q42 be large enough so that the current is hard to be influenced by noise. In this example, the analog current Io is (I2−I1)×M. By adding I1×M to the analog current Io and dividing it by M in the current addition/subtraction circuit 113, the control current Idac will be in a range from the control current I1 to I2.

For example if the reference current Iref is supplied to the MOS transistor Q41, weighted current tries to flow the MOS transistors Q42 to Q45. The MOS transistors Q52 to Q55 are turned on and off by an appropriate bit of the control data DF, current of the corresponding MOS transistors Q42 to Q45 are added to each so as to supply the analog current Io to the node N12.

In this example, although the DAC 110 is configured to switch only the analog current Io by weightings of the size ratio of the MOS transistors, the analog current Io can be generated by other configuration. For example, by providing several MOS transistors having the same size ratio, decoding the control data DF to a thermo meter code that corresponds to each MOS transistor, and stacking current of each MOS transistor by 1LSB according to the thermo meter code. Weighting and thermo meter code can be combined to form the DAC 110.

The current addition/subtraction circuit 113 is constituted of MOS transistors Q14, Q15, and Q16. The MOS transistor Q14 is connected with the MOS transistor Q11 to form a current mirror. To be more specific, a source of the MOS transistor Q14 is connected to a power supply potential, a gate is connected to a gate and a drain of the MOS transistor Q11, and a drain is connected to the node N12. In this example, a size of the MOS transistor Q14 is M times a size of the MOS transistor Q11. The MOS transistor Q15 and Q16 are connected to form current mirrors. To be more specific, sources of the MOS transistors Q15 and Q16 are connected to a ground potential, gates are connected to each other, and the gates are also commonly connected to a drain of the MOS transistor Q15. Further, a drain of the MOS transistor Q15 is connected to the node N12. A drain of the MOS transistor A16 is connected to the CCO 111. In this example, a size of the MOS transistor Q15 is M times a size of the MOS transistor Q16.

For example if the control current I1 flows to the MOS transistor Q11, the control current I1×M flows to the MOS transistor Q14. Then the analog current Io, which is the converted control data DF, flows from the MOS transistors Q52 to Q55. Further, the control current I1×M flows from the MOS transistor Q14 to the node N12. As a result, a current value of the node N12 becomes; current Io+control current I1×M=(I1 to I2)×M, and then the current is supplied to the MOS transistor Q15. A current (I1 to I2)×M/M=I1 to I2 flows to the MOS transistor Q16, and the current becomes the control current Idac to be supplied to the CCO 111.

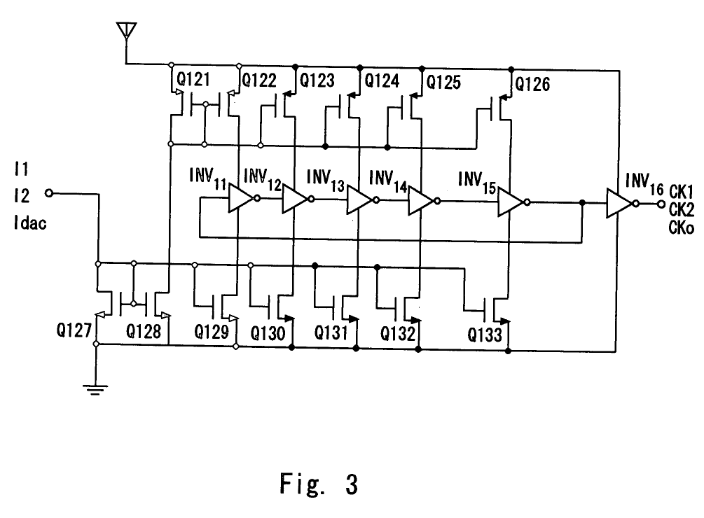

Circuit configurations of the CCO 111, CCO 106a, and CCO are described hereinafter with reference to FIG. 3. In this embodiment, the CCO 111, CCO 106a and 106b have the same circuit configuration and the similar characteristics. To bring the characteristics closer to identical, it is preferable that the CCO 111, the CCOs 106a and 106b are formed on the same-semiconductor chip.

The CCOs are comprised of P-channel MOS transistors Q121 to Q126, N-channel MOS transistors Q127 to Q133, and inverters INV11 to INV16.

The MOS transistor Q127 and the MOS transistors Q128 to Q134 are connected to form current mirrors. A constant current equal to or a several times of the control current I1, I2, or Idac is supplied to the MOS transistors Q128 to Q133 as a drain current.

Similarly, the MOS transistor Q121 and the MOS transistors Q122 to Q126 are connected to form current mirrors. A constant current equal to or a several times of the control current I1, I2, or Idac is supplied to the MOS transistors Q122 to Q126 as a drain current.

The MOS transistors Q122 and Q129, and the inverter INV11 form a first stage delay element. The MOS transistor Q123 and Q130, and the inverter INV12 form a second stage delay element. The MOS transistor Q124 and Q131, and the INV13 form a third stage delay element. Similarly, the MOS transistor Q125 and Q132, and the inverter INV14 form a fourth stage delay element. The MOS transistor Q126 and Q133, and the inverter INV15 form a fifth stage delay element. A ring oscillator is formed by only the odd number stages of delay elements being connected in a ring (five stages in an example of FIG. 3). An oscillation frequency of the ring oscillator is controlled by the control current I1, I2 or Idac.

The inverter INV16 inverts an output clock from the fifth stage delay element, constituted of the MOS transistor Q126 and Q134, and the inverter INV15. The inverter INV16 also shapes a waveform of the output clock so as to output as a clock CK1, CK2, or CKo.

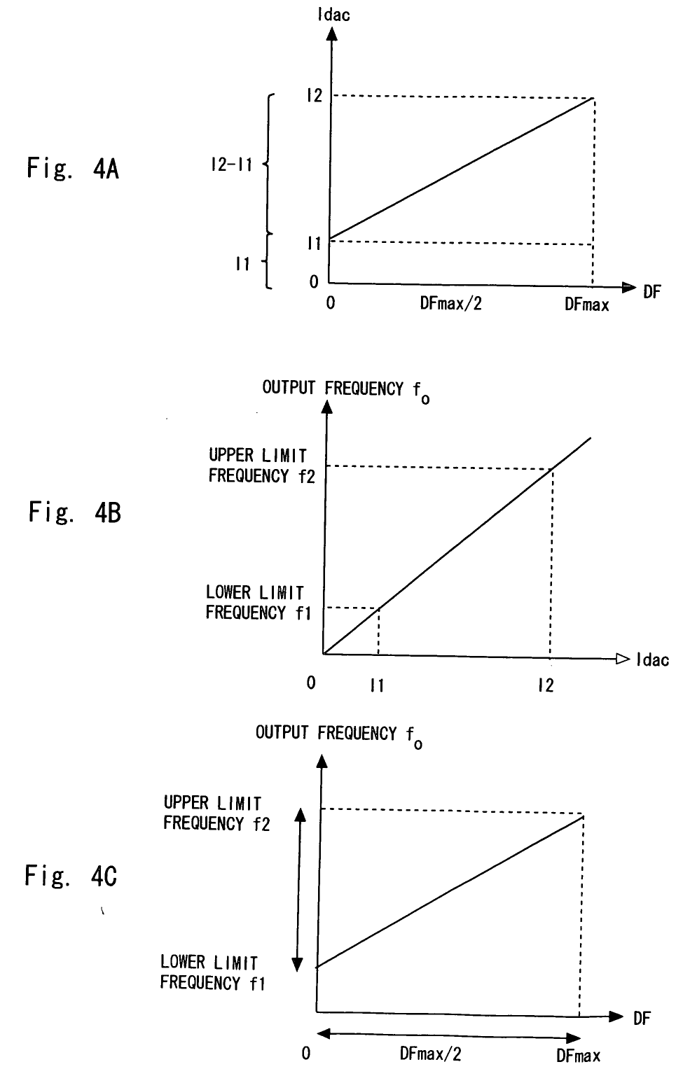

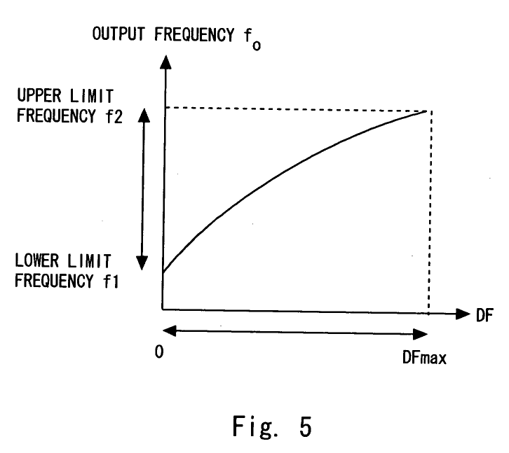

A characteristic of the digital control oscillator of this embodiment is described hereinafter in detail with reference to FIGS. 4A to 5. FIG. 4A shows a characteristic of the control data DF—the control current Idac in the DAC 110. FIG. 4B shows a characteristic of the control current Idac—the output frequency fo in the CCO 111. The FIG. 4C shows a characteristic of the control data DF—the output frequency fo in the digital control oscillator.

As shown in FIG. 4A, when the control data DF in a range from a lower limit 0, to an upper limit DFmax is inputted to the DAC 110, the DAC 110 outputs a control current Idac that is in proportion to the control data DF. In this embodiment, the DAC 110 performs D/A conversion with “the control current I2−the control current I1=the reference current Iref” to be a maximum current of the output, meaning in a range from 0 to the reference current Iref. The current addition/subtraction circuit 113 adds the control current I1 to the converted analog current Io, and the control current Idac will be a current in a range from the control current I1 to the control current I2. Therefore as shown in FIG. 4A, when the control data DF is the lower limit value “0”, the control current Idac, that is supplied to the CCO 11, becomes the control current I1. On the other hand when the control data DF is the upper limit value DFmax, the control current Idac becomes the control current I2.

As shown in FIG. 4B, the CCO 111 outputs a clock CKo having an output frequency fo that is in proportion to the control current Idac being inputted. In this example, the output current Idac is in a range from the control current I1 to the control current I2. When the control current I1 is inputted, the output frequency fo is the lower limit frequency f1. When the control current I2 is inputted, the output frequency fo is the upper limit frequency f2.

By combining the characteristic of the DAC 110 shown in FIG. 4A and that of the CCO 111 shown in FIG. 4B, a characteristic of the digital control oscillator of this embodiment will be the one shown in FIG. 4C. Specifically, the digital control oscillator outputs a clock CKo having the output frequency fo in proportion to the control data DF in a range from the lower limit value “0” to the upper limit value DFmax. When the control data DF is the lower limit value “0”, the control current I1 is inputted to the CCO 111, and the output frequency fo will be the lower limit frequency f1. When the control data DF is the upper limit value DFmax, the control current I2 is inputted to the CCO 111, and the output frequency fo will be the upper limit frequency f2.

The lower limit frequency f1 is an oscillation frequency locked by the PLL 100a, while the upper limit frequency f2 is an oscillation frequency locked by the PLL 100b. The lower and the upper limit frequency f1 and f2 do not fluctuate even with a change in an environment etc. Therefore, the upper and the lower limit frequency against the control data DF are always fixed, making the frequency variable range be constant.

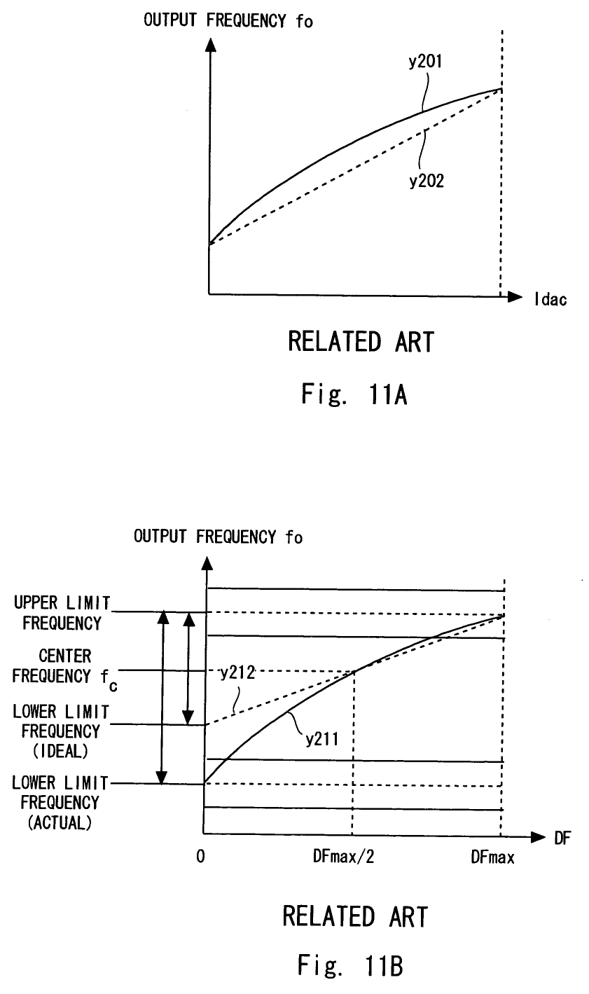

FIG. 5 shows a characteristic of the control data DF—the output frequency fo in the digital control oscillator. FIG. 5 shows the characteristic in a case the characteristic of the CCO is a curved line as in FIGS. 11A and 11B.

In this case, as the output frequency fo to the control current Idac in the CCO111 is curved, the output frequency fo as against the control data DF in the digital control oscillator is also curved, as shown in FIG. 5.

However in this embodiment, when the control data DF is the lower limit value “0”, the output frequency fo will be the lower limit frequency f1, as with FIGS. 4A to 4C. Further, when the control data DF is the upper limit value DFmax, the control data DF will be the upper limit frequency f2. The frequency variable range can therefore be constant in this case as well.

With this embodiment as described in the foregoing, by setting the variable range of the control current Idac to be supplied to the CCO 111, which is an output oscillator, to a range between the control current I1 to the control current I2 at any time, it is possible to always keep the output frequency fo to be in a range from the lower limit frequency f1 to the upper limit frequency f2, and thereby keeping the frequency variable range to be a desired value. This enables to improve the frequency resolving power of the digital control oscillator, meaning that the number of bits of DAC input can be smaller to obtain an equivalent frequency resolving power, accordingly reducing an area of DAC circuit.

The PLLs 100a and 100b generate the control currents I1 and I2, which are necessary for outputting the lower limit frequency f1 and the upper limit frequency f1 of the frequency variable range. Using the control currents I1 and I2 as a reference, the PLLs 100a and 100b supply a current in a range from the control current I1 to the control current I2 to the CCO 111. By providing the CCO 110, the CCO106a, which is an oscillator of the PLL 100a, and the CCO 106b, which is an oscillator of the PLL 100b in the same circuit, in the same circuit, it is possible to accurately suppress a characteristic fluctuation caused by variations in production tolerance and a change in an environment including a temperature and a power supply change.

If it is designed to make the input current—output frequency characteristic (Idac—fo characteristic) in the CCO to be almost linear, it is possible to define a relationship between the control data DF and the output frequency fo of the digital control oscillator almost as unique regardless of condition.

### Second Embodiment

A digital control oscillator according to a second embodiment of the present invention is described hereinafter in detail. The digital control oscillator of the present invention is characterized in that three points, which are an upper limit, a lower limit, and a center point of an output frequency, are controlled to be fixed using three PLLs.

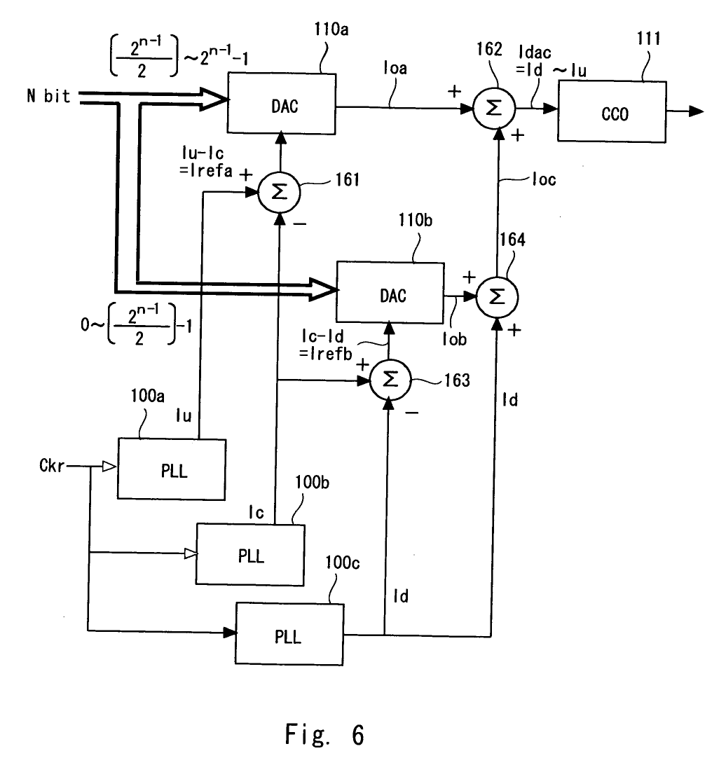

A configuration of the digital control oscillator of the this embodiment is described hereinafter in detail with reference to FIG. 6. In FIG. 6, components identical to those in FIG. 1 are denoted by reference numerals identical to those therein with detailed description omitted.

Similar to FIG. 1 as shown in FIG. 6, the digital control oscillator comprises PLLs 100a and 100b, and a CCO 111, and PLL100c, which is the same as the PLLs 100a and 100b, and DACs 110a and 110b, which are the same as the DAC 110 in FIG. 1, and current addition/subtraction circuits 161 to 164.

The PLL 100a, 100b, and 100c generate control current Iu, Ic, and Id respectively. The PLL 100a generates the control current Iu according to the reference clock CKr, and also locks the oscillation frequency to the frequency fu by the control current Iu. The PLL 100b generates a control current Ic according to the reference clock CKr, and also locks the oscillation frequency to the frequency fc by the control current Ic. The PLL 100c generates a control current Id according to the reference clock CKr, and also locks the oscillation frequency to the frequency fd by the control current Id. In this example, the frequency fd is a lower limit frequency of the output frequency fo. The frequency fu is an upper limit frequency of the output frequency fo. The frequency fc is a center frequency of the output frequency fo.

The current addition/subtraction circuit 161 subtracts the control current Ic of the PLL 100b from the control current Iu of the PLL 100a, and supplies a differential signal to the DAC 110a as a reference current Irefa. The current addition/subtraction circuit 163 subtracts the control current Id of the PLL 100c from the control current Ic of the PLL 100b, and supplies a differential signal to the DAC 110b as a reference current Irefb.

The DAC 110a converts 2ⁿ⁻¹/2 to 2ⁿ⁻¹ of a N bit control data supplied externally (for example if DF is 8 bit, 128 to 255) into the analog current Ioa. In this embodiment, the DAC 110a takes the reference current Irefa as a maximum reference current so as to generate an analog current Ioa with the reference current Irefa (i.e. current control Iu−ic) as an upper limit.

The DAC 110b converts 0 to 2ⁿ⁻¹/2-1 of the N bit control data supplied externally (for example if DF is 8 bit, 0 to 127) into the analog current Iob. In this embodiment, the DAC 110b takes the reference current Irefb as a maximum reference current so as to generate an analog current Iob with the reference current Irefa (i.e. current control Ic−id) as an upper limit.

The current addition/subtraction circuit 164 supplies a signal, in which a control current Id of the PLL 100c being added to an analog current Iob of the DAC 110b, to the current addition/subtraction circuit 164 as an analog current Ioc.

The current addition/subtraction circuit 162 adds the analog current Ioa of the DAC 110a to the analog current Ioc of the current addition/subtraction circuit 164, and supplies the added signal to the CCO 111 as the control current Idac. Specifically, the current addition/subtraction circuit 162 converts the analog currents Ioa and Ioc into the control current Idac, with a center to be the control current Ic in a range from the control current Id to the control current Iu.

The CCO 111 outputs the clock CKo having the output frequency fo corresponding to the control current Idac, which is supplied from the current addition/subtraction circuit 162. The CCO 111 generates the clock CKo having the output frequency fo, whose center frequency is fc in a range from the lower frequency fd to the upper frequency fu.

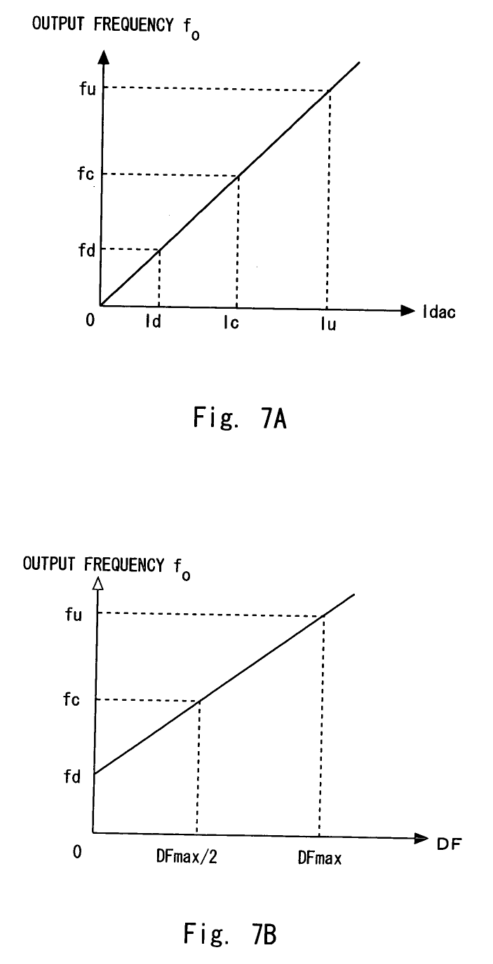

A characteristic of the digital control oscillator of this embodiment is described hereinafter with reference to FIGS. 7A and 7B. FIG. 7A shows a characteristic of the control current Idac—the output frequency fo in the CCO 111. FIG. 7B shows a characteristic of the control data DF—the output frequency fo in the digital control oscillator.

In this example as shown in FIG. 7A, the center of the control current Idac is the control current Ic in a range from the control current Id to the control current Iu. With the control current Id, the output frequency fo becomes the lower limit frequency fd. With the control current Iu, the output frequency fo becomes the upper limit frequency fu. With the control current Ic, the output frequency fo becomes the center frequency fc.

A characteristic of the digital control oscillator of this embodiment is shown in FIG. 7B. Specifically, when the control data DF is the lower limit value “0”, the control current I1 is inputted to the CCO 111, and the output frequency fo is the lower limit frequency fd. When the control data DF is the upper limit DFmax, the control current Iu is inputted to the CCO 111, and the output frequency fo will be the upper frequency fu. Further, when the control data DF is the center value DFmax/2, the control current Ic is inputted to the CCO 111, and the output frequency fo will be the center frequency fc.

The upper limit frequency fu is an oscillation frequency locked by the PLL 100a. The lower limit frequency fd id an oscillation frequency locked by the PLL 100c. The center frequency fc is an oscillation frequency locked by the PLL 100b. Accordingly as with the first embodiment, the upper limit, the lower limit, and center frequencies do not fluctuate at any time even with a change in an environment etc. Therefore, the upper limit, the lower limit and center frequencies as against the control data DF are always fixed, thereby keeping the frequency variable range to be constant and also suppressing a fluctuation of center frequency.

As described so far in this embodiment, the output frequency fo can always be in a range from the lower limit frequency f1 to the upper limit frequency f1 as well as the center frequency to being fc, by keeping the variable range of the control current Idac to be supplied to the CCO 111, an output oscillator, in a range from the control current Id to the control current Iu, and by making the center to be the control current Ic, using two DACs and three PLLs. This keeps the frequency variable range to be a desired value as with the first embodiment, thereby improving the frequency resolving power. Further by fixing the center frequency fc, a characteristic fluctuation of the center frequency can be suppressed to be more ideal characteristic, even in a case a characteristic is curved as in FIG. 5.

### Other Embodiment

In the first embodiment, two points of the output frequency are fixed, and in the second embodiment, three points of the output frequency are fixed. However it is not restricted to those embodiments but may have more DAC or PLL and more points may be fixed. Fixing more points better suppresses a characteristic fluctuation in a case a characteristic of the CCO is curved. Furthermore, dividing the control data DF being inputted into several DACs to input the control data DF reduces a load to each of the DAC, leading to a faster process.

In the above example, although the DAC is a current output type and the oscillator is CCO, it is not restricted to the above embodiments but the DAC may be a voltage output type and the oscillator may be a VCOI for voltage control. Using a voltage output type DAC or CCO facilitates an addition/subtraction of current values using current mirror etc, which realizes a simple circuit configuration and faster operating speed.

It is apparent that the present invention is not limited to the above embodiment and it may be modified and changed without departing from the scope and spirit of the invention.

What is claimed is:

1. A digital control oscillator comprising:
a reference signal generation circuit for generating a first reference signal of a first signal level, and a second reference signal of a second signal level;
a conversion circuit for referring to the first and the second reference signals, and converting a digital signal being inputted into an analog output control signal in a range from the first signal level to the second signal level; and
an output oscillator for outputting clocks having a frequency corresponding to the output control signal.

2. The digital control oscillator according to claim 1, wherein the conversion circuit converts the digital signal into an analog signal based on a differential signal, obtained by subtracting the first signal level from the second signal level, and generates the output control signal by adding the first signal level to a level of the converted analog signal.

3. The digital control oscillator according to claim 1, wherein the reference signal generation circuit comprises:
a first PLL circuit for generating the first reference signal, and being controlled to a first frequency by the first reference signal;
a second PLL circuit for generating the second reference signal, and being controlled to a second frequency by the second reference signal;

4. The digital control oscillator according to claim 3, wherein the first PLL circuit includes a first PLL oscillator for generating a clock having the first frequency corresponding to the first reference signal;
the second PLL circuit includes a second PLL oscillator for generating a clock having the second frequency corresponding to the second reference signal; and
a circuit configuration of the output oscillator is identical to circuit configurations of the first and the second PLL oscillator.

5. The digital control oscillator according to claim 4, wherein the first PLL circuit comprises:
the first PLL oscillator;
a first divider for dividing an output clock of the first PLL oscillator, and generating a first divided clock;
a second divider for dividing a reference clock being inputted, and generating a second divided clock;
a first phase detector for generating a first phase difference signal corresponding to a phase difference between the first divided clock and the second divided clock; and
a reference signal conversion circuit for converting into the first reference signal according to the first phase difference signal; and
wherein the second PLL circuit comprises:
the second PLL oscillator;
a third divider for dividing an output clock of the second PLL oscillator, and generating a third divided clock;
a fourth divider for dividing a reference clock being inputted, and generating a fourth divided clock;
a second phase detector for generating a second phase difference signal corresponding to a phase difference between the third divided clock and the fourth divided clock; and
a reference signal conversion circuit for converting into the second reference signal according to the second phase difference signal.

6. The digital control oscillator according to claim 5, wherein the first frequency is defined by a dividing ratio of the first and the second dividers, and
the second frequency is defined by a dividing ratio of the third and the fourth dividers.

7. The digital control oscillator according to claim 1, wherein the output oscillator is a current control oscillator for controlling an oscillation frequency according to an input current.

8. The digital control oscillator according to claim 4, wherein the first and the second PLL oscillators are current control oscillator for controlling an oscillation frequency according to an input current.

9. The digital control oscillator according to claim 1, wherein the reference signal generation circuit generates a third reference signal of a third signal level;
the conversion circuit refers to the first and the second reference signal, and converts a first range signal among the digital signal being inputted into the output control signal in a range from the first signal level to the second signal level; and
the conversion circuit refers to the second and the third reference signal, and converts a second range signal among the digital signal being inputted into the output control signal in a range from the second signal level to the third signal level.

10. A digital control oscillator comprising:
a conversion circuit for converting a digital signal being inputted to an analog output control signal;
an output oscillator for outputting a clock having a frequency corresponding to the output control signal; and
a control circuit for controlling an upper limit value and a lower limit value of the output control signal to specified values.

11. The digital control oscillator according to claim 10, wherein the control circuit supplies a first reference signal corresponding to the lower limit value of the output control signal and a second reference signal corresponding to the upper limit value of the output control signal to the conversion circuit.

12. The digital control oscillator according to claim 11, wherein the conversion circuit generates an analog signal, with an upper limit being a value obtained by subtracting the first reference signal from the second reference signal, and generates the output control signal by adding the first reference signal to the generated analog signal.

13. The digital control oscillator according to the claim 11, wherein the control circuit comprises:
a first PLL circuit for oscillating with a first frequency corresponding a first current, and outputting the first current as the first reference signal; and
a second PLL circuit for oscillating with a second frequency corresponding a second current, and outputting the second current as the second reference signal.

14. The digital control oscillator according to claim 13, wherein the conversion circuit comprises:
a first current mirror circuit for outputting the first current for controlling the lower limit value of the output control signal, and for controlling an oscillation of the first frequency; and
a second current mirror circuit for outputting the second current for controlling the upper limit value of the output control signal, and for controlling an oscillation of the second frequency.

15. The digital control oscillator according to claim 10, wherein the control circuit controls any value in a range from the upper limit value to the lower limit value of the output signal to a specified value.
